(19) United States
(12) Patent Application Publication
(10) Pub. No.: US 2015/0364574 A1
(43) Pub. Date: Dec. 17, 2015

(54) SEMICONDUCTOR DEVICES AND METHODS OF MANUFACTURING THE SAME

(71) Applicant: Samsung Electronics Co., Ltd., Suwon-Si (KR)

(72) Inventors: Ju-Youn KIM, Suwon-si (KR); Dong-Hyun ROH, Suwon-si (KR); Sang-Duk PARK, Hwaseong-si (KR); Il-Young YOON, Hwaseong-si (KR); Jeong-Nam HAN, Seoul (KR); Jong-Mil YOUN, Yongin-si (KR)

(21) Appl. No.: 14/579,627

(22) Filed: Dec. 22, 2014

(30) Foreign Application Priority Data
Jun. 16, 2014 (KR) 10-2014-0073018

(51) Int. Cl. H01L 29/66; H01L 21/3105; H01L 21/8234; H01L 29/06; H01L 21/3213; H01L 27/088; H01L 21/02; H01L 21/311

(52) U.S. Cl. CPC H01L 29/66545; H01L 21/02123; H01L 21/31053; H01L 21/31116; H01L 21/0214; H01L 21/0217; H01L 29/66636; H01L 21/31144; H01L 21/31111; H01L 29/0642; H01L 21/32135; H01L 27/088; H01L 21/823437

(57) ABSTRACT

In a method of manufacturing a semiconductor device, a dummy gate structure including a dummy gate insulation layer pattern, a dummy gate electrode and a gate mask sequentially stacked are formed on a substrate. An interlayer insulating layer including tonen silazane (TOSZ) is formed on the substrate to cover the dummy gate structure. An upper portion of the interlayer insulating layer is planarized until a top surface of the gate mask is exposed to form an interlayer insulating layer pattern. The exposed gate mask, and the dummy gate electrode and the dummy gate insulation layer pattern under the gate mask are removed to form an opening exposing a top surface of the substrate. The dummy gate insulation layer pattern is removed using an etchant including hydrogen fluoride (HF), but the interlayer insulating layer pattern remains. A gate structure is formed to fill the opening.

### CROSS-REFERENCE TO RELATED APPLICATION

This application claims priority under 35 USC §119 to Korean Patent Application No. 10-2014-0073018, filed on Jun. 16, 2014 in the Korean Intellectual Property Office (KIPO), the contents of which are herein incorporated by reference in their entirety.

### BACKGROUND

Some example embodiments relate to semiconductor devices and/or methods of manufacturing the same. More particularly, some example embodiments relate to semiconductor devices including a metal gate electrode and/or methods of manufacturing the same.

In a gate-last process, a dummy gate structure including a silicon oxide layer, a polysilicon layer and a silicon nitride layer may be formed, and an interlayer insulating layer covering the dummy gate structure may be formed. When the interlayer insulating layer is formed by using a material having a good gap-fill characteristic, the interlayer insulating layer may be damaged when the silicon oxide layer is removed by using hydrogen fluoride (HF). In order to mitigate or prevent the damage to the insulating interlayer, another layer may be formed on the interlayer insulating layer using a material having a tolerance to hydrogen fluoride (HF), however, the gate-last process may be complicated.

### SUMMARY

Some example embodiments provide a method of manufacturing a semiconductor device having good characteristics by simple processes.

Some example embodiments provide a semiconductor device having good characteristics.

According to some example embodiments, there is provided a method of manufacturing a semiconductor device. In the method, a dummy gate structure including a dummy gate insulation layer pattern, a dummy gate electrode and a gate mask sequentially stacked are formed on a substrate. An interlayer insulating layer including tonen silazane (TOSZ) is formed on the substrate to cover the dummy gate structure. An upper portion of the interlayer insulating layer is planarized until a top surface of the gate mask is exposed to form an interlayer insulating layer pattern. The exposed gate mask, and the dummy gate electrode and the dummy gate insulation layer pattern thereunder are removed to form an opening exposing a top surface of the substrate. The dummy gate insulation layer pattern is removed by using an etchant including hydrogen fluoride (HF), but the interlayer insulating layer pattern remains. A gate structure is formed to fill the opening.

In one example embodiment, an oxygen plasma treatment may be performed on the interlayer insulating layer pattern.

In one example embodiment, before forming the interlayer insulating layer, a gate spacer including a low-k dielectric material containing oxygen may be formed on a sidewall of the dummy gate structure. The interlayer insulating layer may be formed on the substrate to cover the dummy gate structure and the gate spacer.

In one example embodiment, the gate spacer may be formed of silicon oxynitride (SiON) or silicon oxycarbonitride (SiOCN).

In one example embodiment, after forming the gate spacer, an etch stop layer may be formed on the dummy gate structure, the gate spacer and the substrate. The interlayer insulating layer may be formed on the etch stop layer, and the interlayer insulating layer pattern may be formed by planarizing an upper portion of the interlayer insulating layer until a top surface of the etch stop layer is exposed.

In one example embodiment, the etch stop layer may be formed of silicon nitride.

In one example embodiment, before forming the etch stop layer, an upper portion of the substrate may be etched by using the dummy gate structure and the gate mask as an etching mask to form a recess. An epitaxial layer may be formed to fill the recess. The etch stop layer may be formed on the dummy gate structure, the gate spacer and the epitaxial layer.

In one example embodiment, a contact plug may be further formed through the interlayer insulating layer pattern and the etch stop layer to contact the epitaxial layer.

In one example embodiment, the dummy gate electrode may be formed of polysilicon, and the gate mask may be formed of silicon nitride.

In example embodiments, a dry etch process may be performed to remove the exposed gate mask.

In one example embodiment, a wet etch process may be further performed by using phosphoric acid (H₃PO₄) as an etchant to remove the exposed gate mask.

In one example embodiment, a gate insulation layer pattern, a high-k dielectric layer pattern and a metal gate electrode may be sequentially stacked on the substrate to form the gate structure.

In one example embodiment, the gate insulation layer pattern may be formed on the exposed surface of the substrate, the high-k dielectric layer pattern may be formed on a top surface of the gate insulation layer pattern and a sidewall of the opening, and the metal gate electrode may be formed on the high-k dielectric layer pattern so that a bottom surface and a sidewall of the metal gate electrode is surrounded by the high-k dielectric layer pattern.

According to some other example embodiments, there is provided a method of manufacturing a semiconductor device. In the method, an isolation layer is formed on a substrate to define a field region and an active region. The field region is covered by the isolation layer, and the active region is not covered by the isolation layer and but protrudes from the isolation layer. A dummy gate structure including an oxide layer pattern, a dummy gate electrode and a gate mask sequentially stacked is formed on the active region and the isolation layer. An interlayer insulating layer including tonen silazane (TOSZ) is formed on the active region and the isolation layer to cover the dummy gate structure. An upper portion of the interlayer insulating layer is planarized until the gate mask is exposed to form an interlayer insulating layer pattern. The exposed gate mask, and the dummy gate electrode and the oxide layer pattern thereunder are removed to form an opening exposing top surfaces of the active region and the isolation layer. The oxide layer pattern is removed by using an etchant including hydrogen fluoride (HF). A gate structure including a gate insulation layer pattern, a high-k dielectric layer pattern and a metal gate electrode sequentially stacked is formed on the active region to fill at least a portion of the opening.

In one example embodiment, an oxygen plasma treatment may be performed on the interlayer insulating layer pattern.

In one example embodiment, before forming the interlayer insulating layer, a gate spacer including a low-k dielectric material containing oxygen may be formed on a sidewall of the dummy gate structure. The interlayer insulating layer may be formed on the active region and the isolation layer to cover the dummy gate structure and the gate spacer.

In one example embodiment, the dummy gate electrode may be formed of polysilicon, and the gate mask may be formed of silicon nitride. The removing the exposed gate mask may be performed by a dry etch process and/or a wet etch process using phosphoric acid (H₃PO₄) as an etchant.

According to still some other example embodiments, there is provided a semiconductor device. The semiconductor device includes a substrate, a gate structure, a gate spacer, and an interlayer insulating layer. The substrate includes a field region having an isolation layer formed therein, and an active region protruding from the isolation layer. The gate structure is formed on the active region. The gate spacer including a low-k dielectric material containing oxygen is formed on a sidewall of the gate structure. The interlayer insulating layer covers sidewalls of the gate structure and the gate spacer and includes tonen silazane (TOSZ).

In one example embodiment, the active region may extend in a first direction, and a plurality of gate structures may be formed in the first direction. The semiconductor device may further include an epitaxial layer on the active region between the plurality of gate structures.

In one example embodiment, the semiconductor device may further include an etch stop layer on a sidewall of the gate spacer and a top surface of the epitaxial layer, and a contact plug contacting the epitaxial layer through the interlayer insulating layer and the etch stop layer.

In one example embodiment, the gate structure may include a gate insulation layer pattern, a high-k dielectric layer pattern, and a metal gate electrode sequentially stacked on the active region.

### BRIEF DESCRIPTION OF THE DRAWINGS

Example embodiments will be more clearly understood from the following detailed description taken in conjunction with the accompanying drawings. FIGS. 1 to 30 represent non-limiting, example embodiments as described herein.

FIGS. 1 to 29 are plan views and cross-sectional views illustrating stages of a method of manufacturing a semiconductor device in accordance with some example embodiments; and

FIG. 30 is a cross-sectional view illustrating a semiconductor device in accordance with another example embodiment.

### DESCRIPTION OF EMBODIMENTS

Various example embodiments will be described more fully hereinafter with reference to the accompanying drawings, in which some example embodiments are shown. The present inventive concepts may, however, be embodied in many different forms and should not be construed as limited to the example embodiments set forth herein. Rather, these example embodiments are provided so that this description will be thorough and complete, and will fully convey the scope of the present inventive concepts to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concepts.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concepts. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concepts.

Unless otherwise defined, all terms (including technical and scientific terms) used herein have the same meaning as commonly understood by one of ordinary skill in the art to which this inventive concepts belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

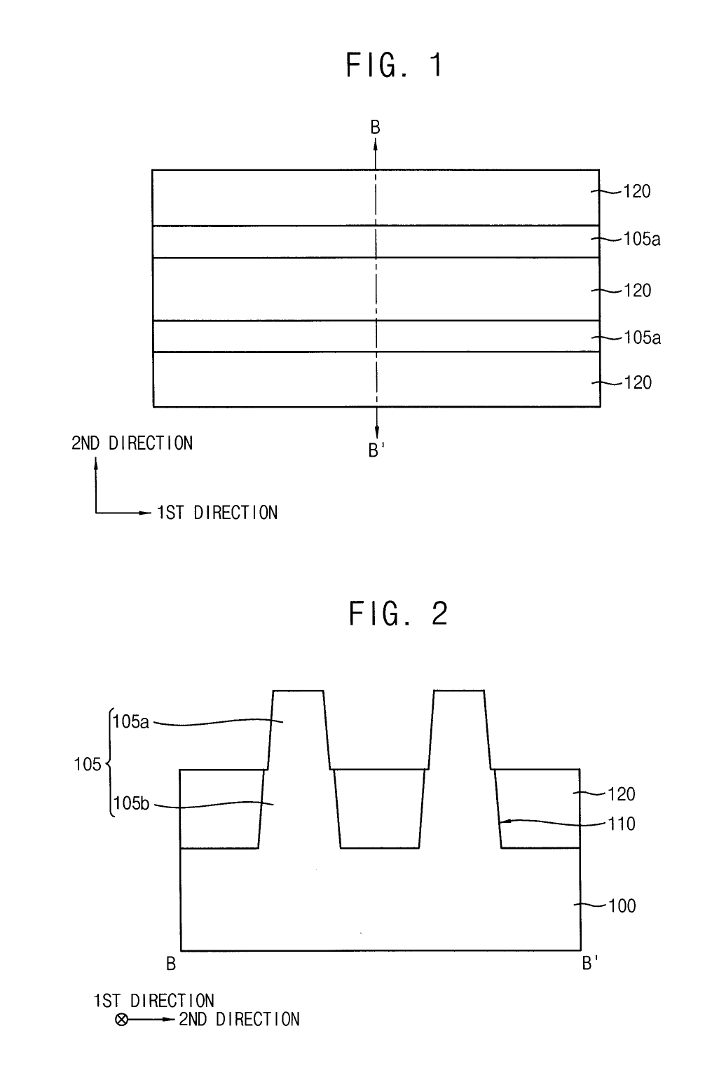

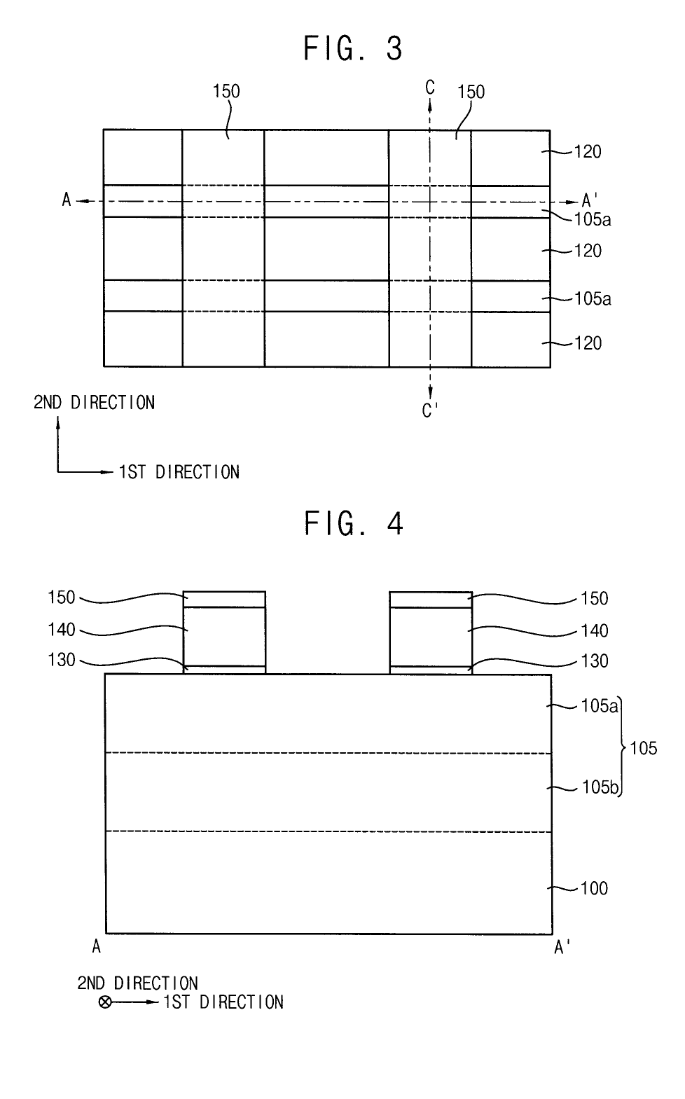

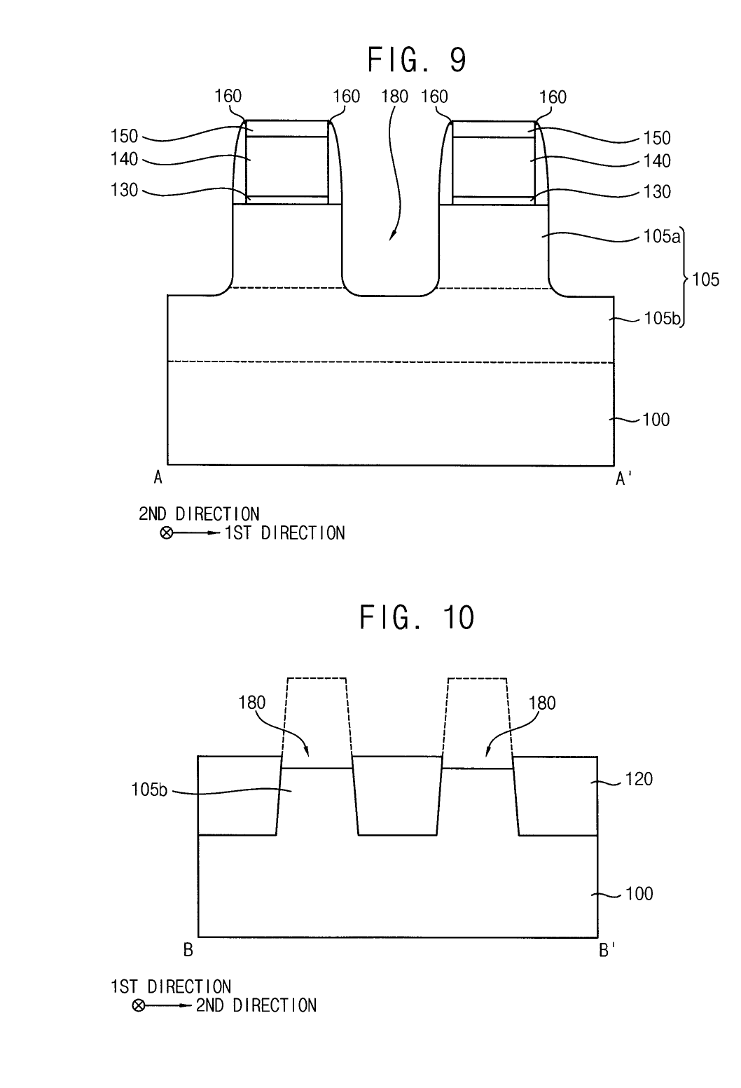

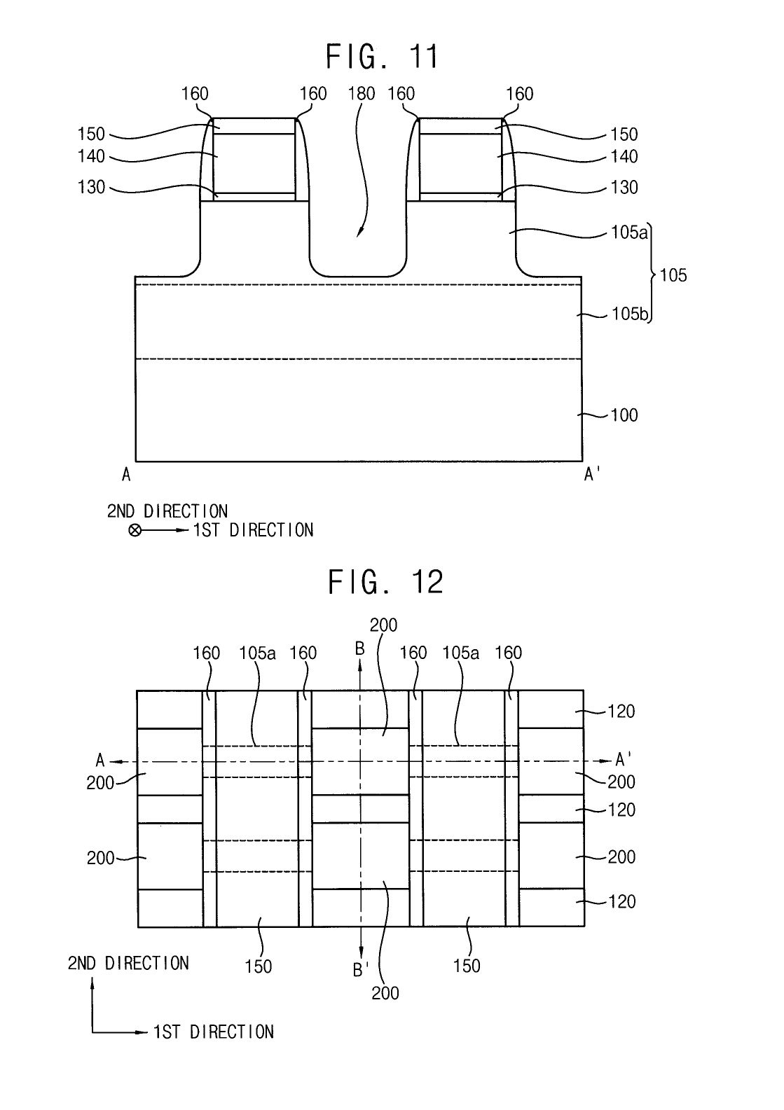

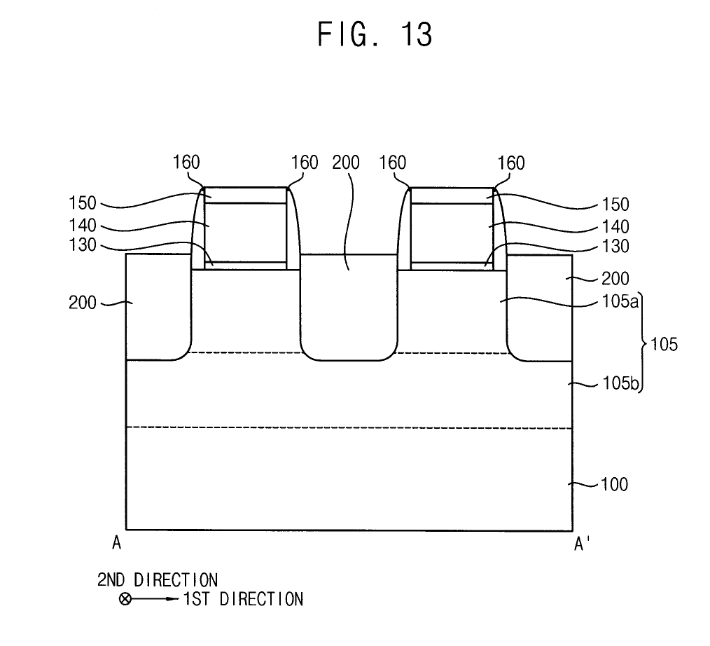

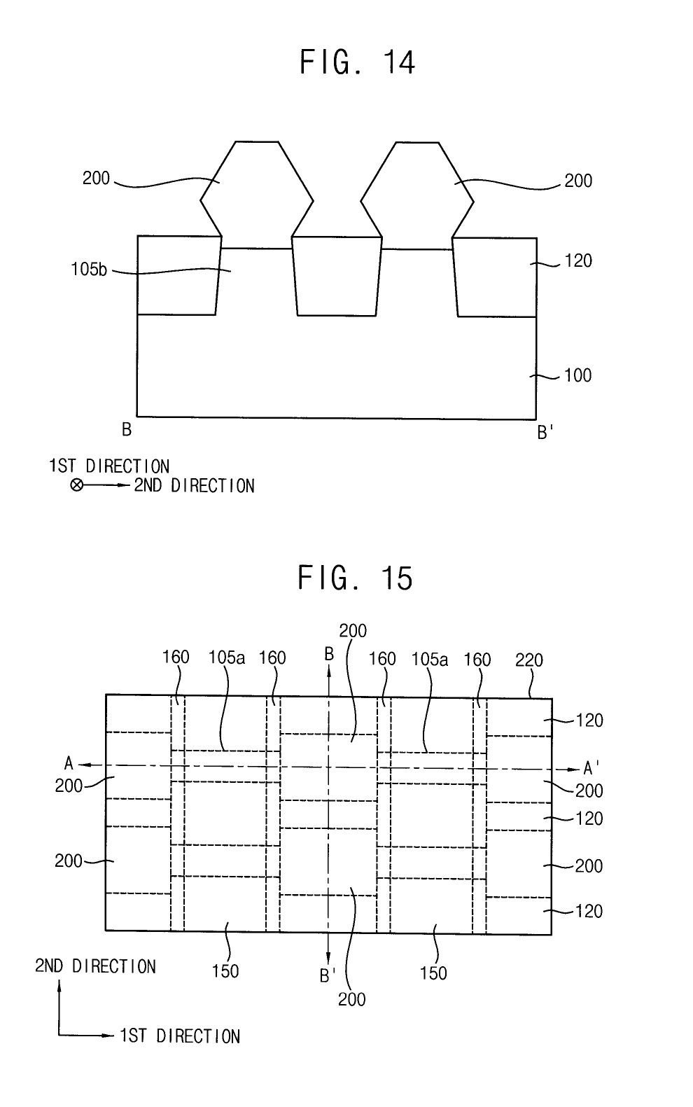

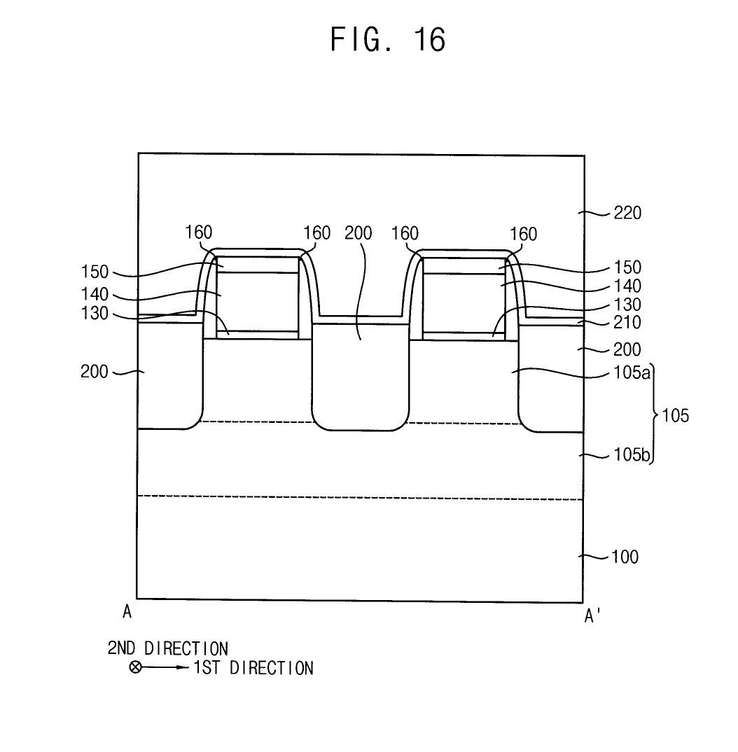

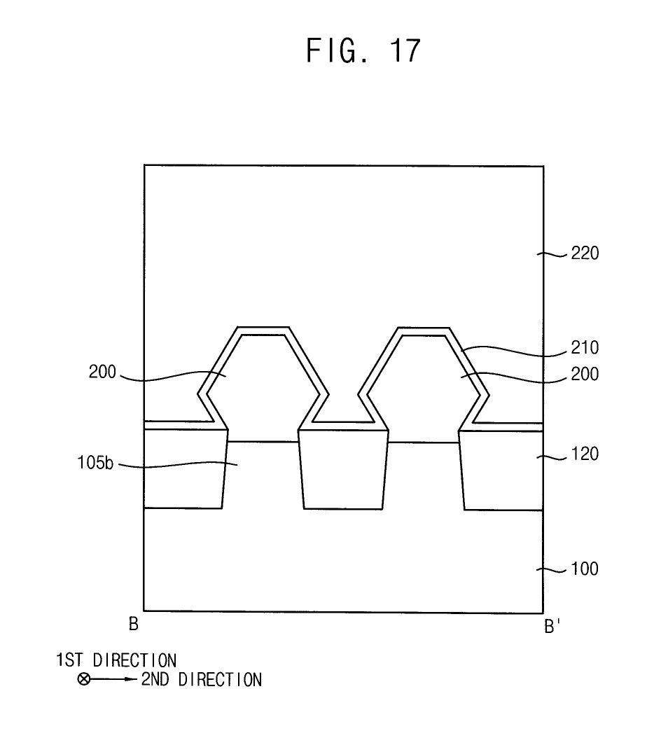

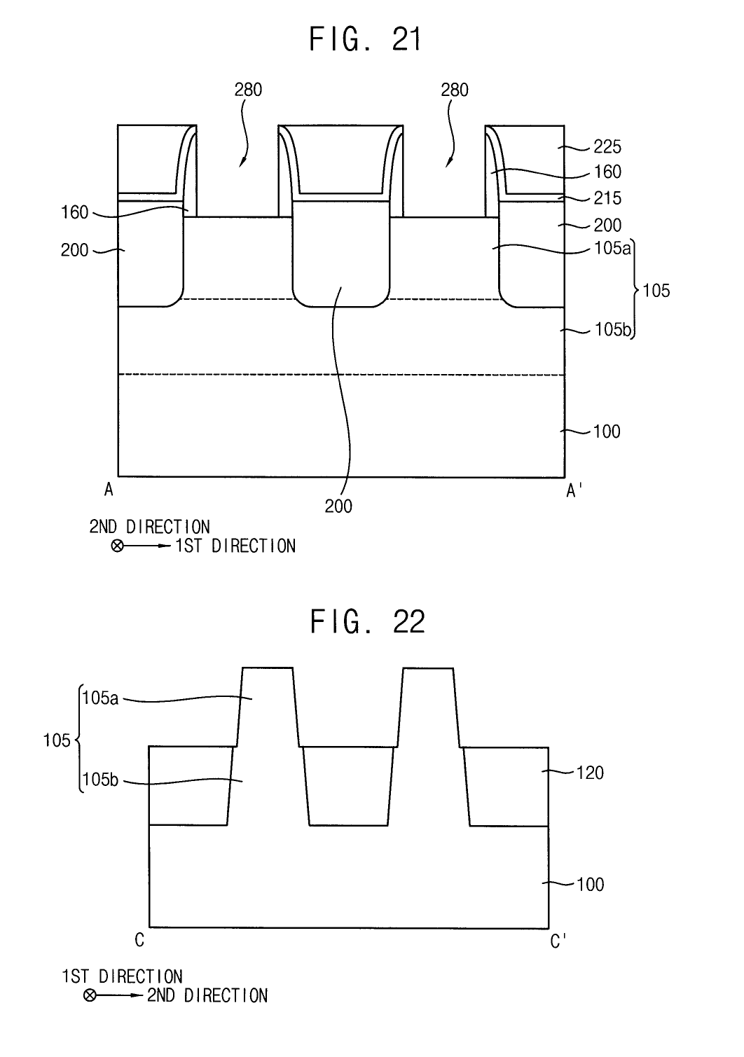

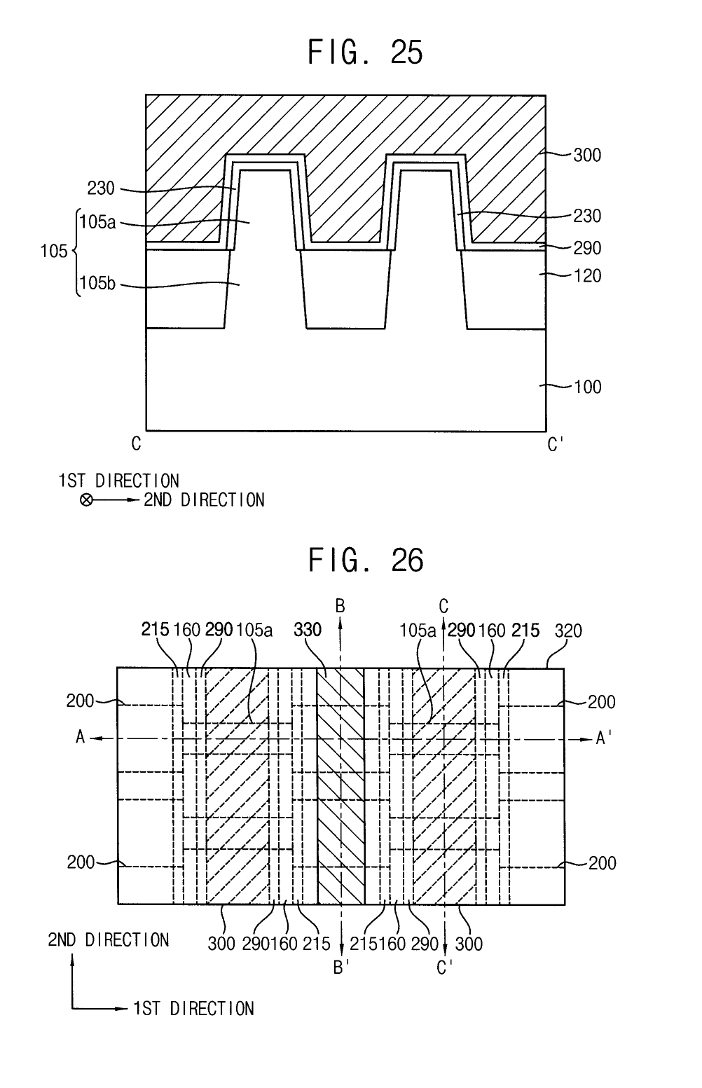

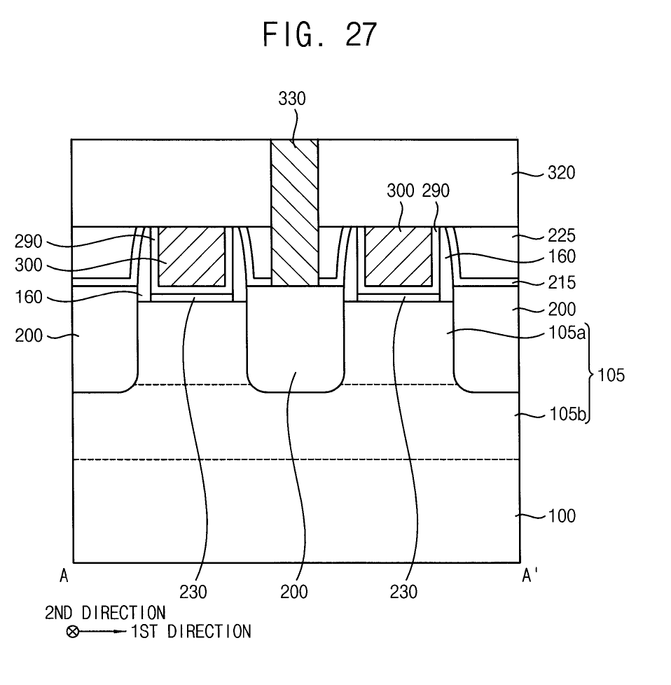

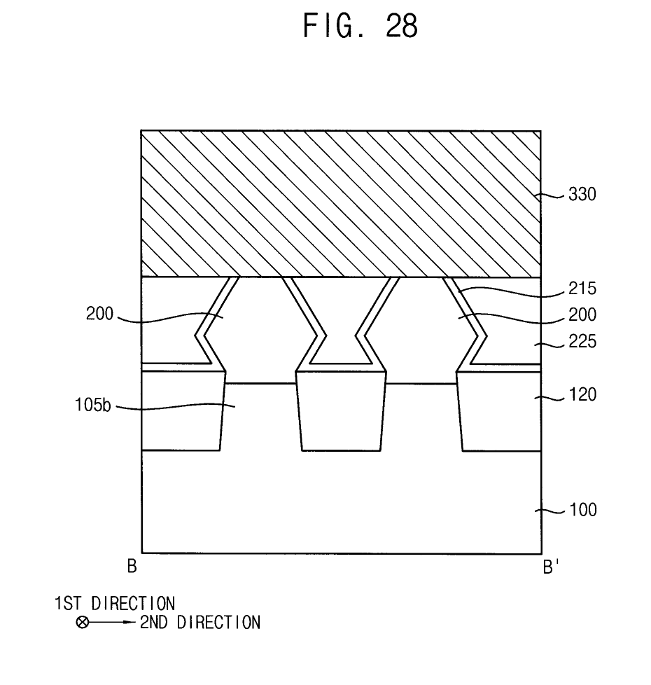

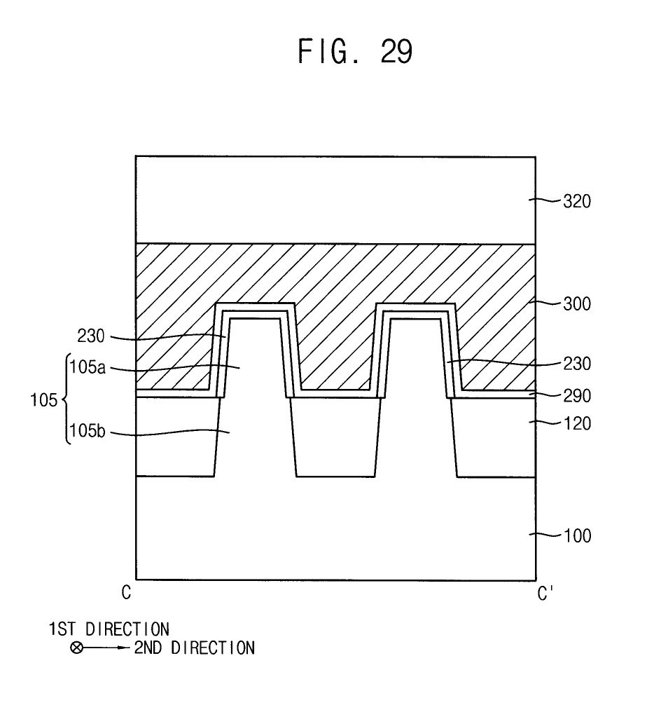

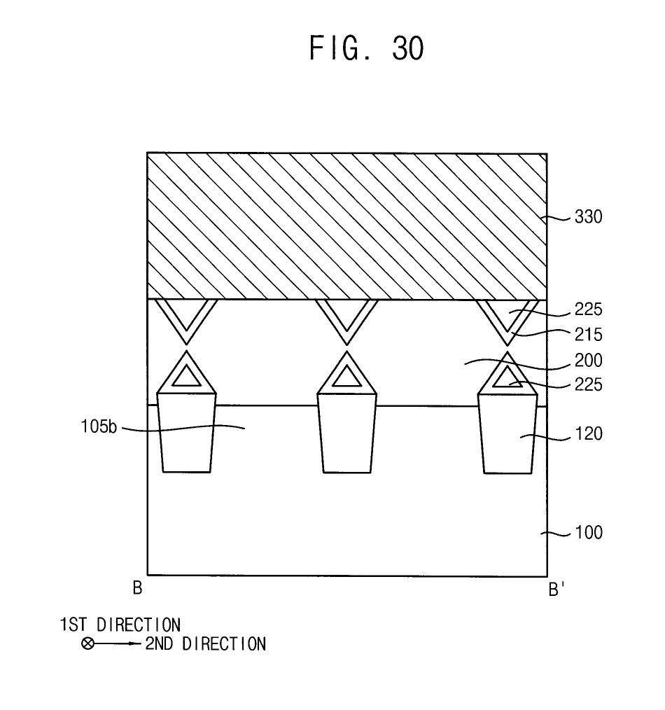

FIGS. 1 to 29 are plan views and cross-sectional views illustrating stages of a method of manufacturing a semiconductor device in accordance with some example embodiments. Particularly, FIGS. 1, 3, 6, 8, 12, 15, 18, 20, 23 and 26 are plan views, and FIGS. 2, 4-5, 7, 9-11, 13-14, 16-17, 19, 21-22, 24-25 and 27-29 are cross-sectional views.

FIGS. 4, 7, 9, 11, 13, 16, 19, 21, 24 and 27 are cross-sectional views cut along a line A-A′ of corresponding plan views, FIGS. 2, 10, 14, 17 and 28 are cross-sectional views cut along a line B-B′ of corresponding plan views, and FIGS. 5, 22, 25 and 29 are cross-sectional views cut along a line C-C′ of corresponding plan views.

Referring to FIGS. 1 and 2, an upper portion of a substrate 100 may be partially removed to form a trench 110, and an isolation layer 120 may be formed on the substrate 100 to fill the trench 110.

The substrate 100 may be a silicon substrate, a germanium substrate, a silicon-germanium substrate, a silicon-on-insulator (SOI) substrate, a germanium-on-insulator (GOI) substrate, or the like.

Before forming the trench 110, an ion implantation process may be performed onto the substrate 100 to form a well region (not shown) therein. In example embodiments, the well region may be formed by implanting p-type impurities, e.g., boron, aluminum, etc., into the substrate 100. Alternatively, the well region may be formed by implanting n-type impurities, e.g., phosphorous, arsenic, etc., into the substrate 100.

In example embodiments, the isolation layer 120 may be formed by forming an insulation layer on the substrate 100 to sufficiently fill the trench 110, planarizing the insulation layer until a top surface of the substrate 100 may be exposed, and removing an upper portion of the planarized insulation layer to expose an upper portion of the trench 110. When the upper portion of the planarized insulation layer is removed, an upper portion of the substrate 100 may be partially removed also to have a reduced width. The insulation layer may be formed of an oxide, e.g., silicon oxide.

According as the isolation layer 120 is formed, a field region having a top surface being covered by the isolation layer 120 and an active region having a top surface not being covered by the isolation layer 120 may be defined in the substrate 100. The active region may protrude from the isolation layer 120 and have a fin-like shape so as to be referred to as an active fin 105. The active fin 105 may include a lower portion 105b and an upper portion 105a protruding from the isolation layer 120. The lower portion 105b may have a sidewall being covered by the isolation layer 120 and a sidewall of the upper portion 105b may not be covered by the isolation layer 120.

In example embodiments, the active fin 105 may extend in a first direction substantially parallel to the top surface of the substrate 100, and a plurality of active fins 105 may be formed in a second direction that may be substantially parallel to the top surface of the substrate 100 and form a given angle with respect to the first direction. In an example embodiment, the second direction may form an angle of 90 degree with respect to the first direction, and thus the first and second directions may be substantially perpendicular to each other.

Referring to FIGS. 3 to 5, a dummy gate structure may be formed on the substrate 100.

The dummy gate structure may be formed by sequentially stacking a dummy gate insulation layer, and a dummy gate electrode layer and a gate mask layer on the active fin 105 of the substrate 100 and the isolation layer 120, patterning the gate mask layer by a photolithography process using a photoresist pattern (not shown) to form a gate mask 150, and sequentially etching the dummy gate electrode layer and the dummy gate insulation layer using the gate mask 150 as an etching mask. Thus, the dummy gate structure may be formed to include a dummy gate insulation layer pattern 130, a dummy gate electrode 140 and the gate mask 150 sequentially stacked on the active fin 105 of the substrate 100 and a portion of the isolation layer 120 adjacent to the active fin 105.

The dummy gate insulation layer may be formed of an oxide, e.g., silicon oxide, the dummy gate electrode layer may be formed of polysilicon, and the gate mask layer may be formed of a nitride, e.g., silicon nitride. The dummy gate insulation layer, the dummy gate electrode layer and the gate mask layer may be formed by a chemical vapor deposition (CVD) process, an atomic layer deposition (ALD) process, or the like. Alternatively, the dummy gate insulation layer may be formed by a thermal oxidation process on an upper portion of the substrate 100.

In example embodiments, the dummy gate structure may be formed to extend in the second direction on the active fins 105 of the substrate 100 and the isolation layer 120, and a plurality of dummy gate structures may be formed in the first direction at a given distance from each other.

After forming the dummy gate structure, an ion implantation process may be performed onto the substrate 100 to form a halo region (not shown) and a lightly doped drain (LDD) region (not shown) therein. In example embodiments, the halo region may be formed by implanting p-type impurities, e.g., boron, aluminum, etc., and the LDD region may be formed by implanting n-type impurities, e.g., phosphorous, arsenic, etc. Alternatively, the halo region may be formed by implanting n-type impurities, and the LDD region may be formed by implanting p-type impurities.

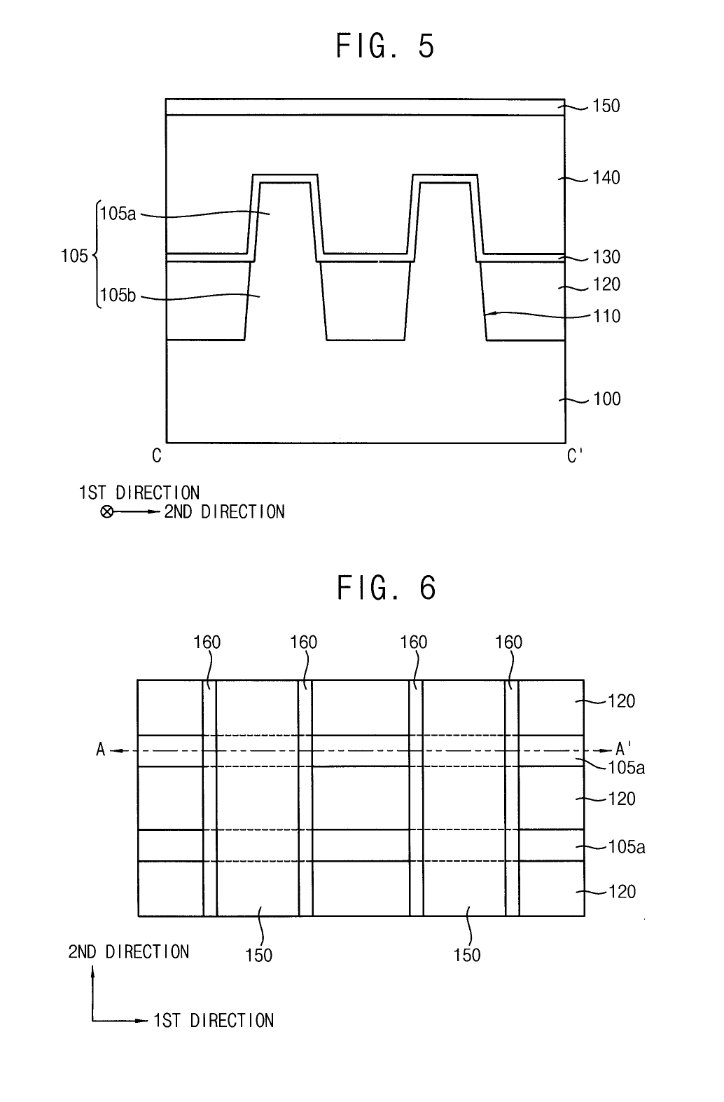

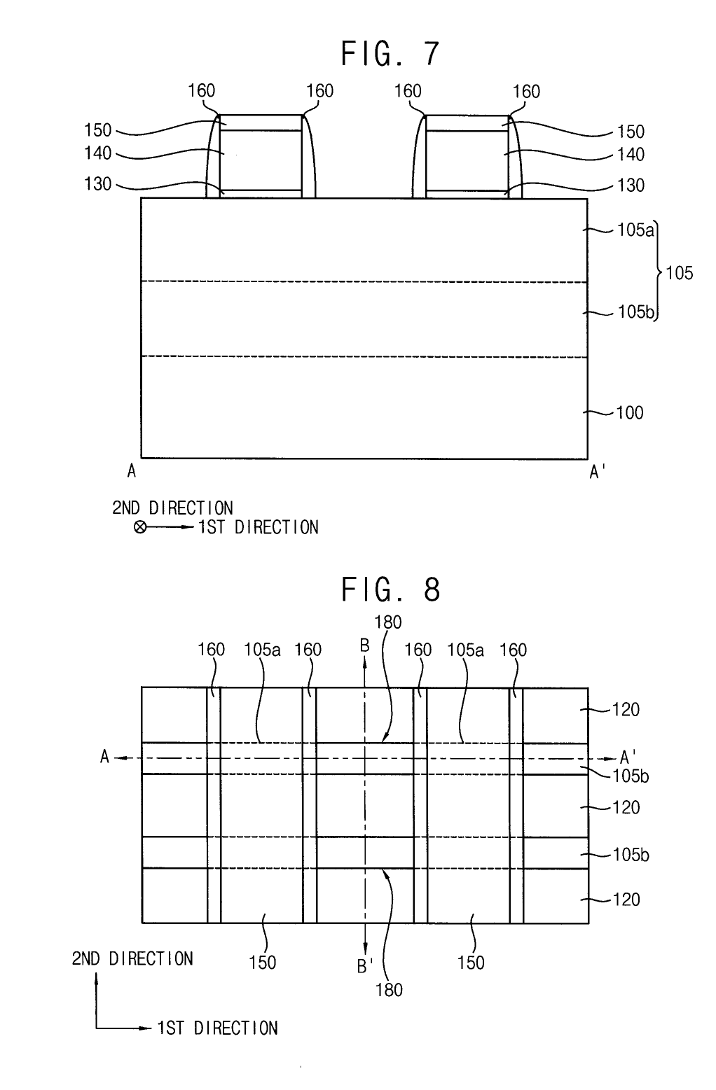

Referring to FIGS. 6 and 7, a gate spacer 160 may be formed on a sidewall of the dummy gate structure. In an example embodiment, a spacer (not shown) may be further formed on a sidewall of the active fin 105.

In example embodiments, the gate spacer 160 may be formed by forming a spacer layer on the dummy gate structure, the active fin 105 and the isolation layer 120, and anisotropically etching the spacer layer. The spacer layer may be formed of a low-k dielectric material containing oxygen, e.g., silicon oxynitride or silicon oxycarbonitride, or the like.

In example embodiments, the gate spacer 160 may be formed on both sidewalls of the dummy gate structure in the first direction.

Referring to FIGS. 8 to 10, a portion of the active fin 105 not covered by the dummy gate structure and the gate spacer 160 may be etched to form a recess 180.

In example embodiments, the recess 180 may be formed by removing the upper portion 105a of the active fin 105 and a portion of the lower portion 105b of the active fin 105. Thus, a bottom surface of the recess 180 may be lower than a top surface of the lower portion 105b of the active fin 105 in which no recess is formed.

Alternatively, referring to FIG. 11, the recess 180 may be formed by removing a portion of the upper portion 105a of the active fin 105, and thus the bottom surface of the recess 180 may be higher than a bottom surface of the upper portion 105a of the active fin 105 in which no recess is formed.

Hereinafter, for the convenience of explanation, only the case in which the bottom surface of the recess 180 is lower than the top surface of the lower portion 105b of the active fin 105 in which no recess is formed will be illustrated.

In example embodiments, the etching process for forming the recess 180 may be performed in-situ with the anisotropic etching process for forming the gate spacer 160 illustrated with reference to FIGS. 6 and 7.

Referring to FIGS. 12 to 14, an epitaxial layer 200 may be formed on the active fin 105 to fill the recess 180.

In example embodiments, the epitaxial layer 200 may be formed by a selective epitaxial growth (SEG) process using a portion of the active fin 105 exposed by the recess 180, i.e., a top surface of the lower portion 105b of the active fin 105 and a sidewall of the upper portion 105a of the active fin 105 as a seed.

In example embodiments, the SEG process may be performed by using a silicon source gas, e.g., disilane (Si₂H₆) gas to form a single crystalline silicon layer. In example embodiments, an n-type impurity source gas, e.g., phosphine (PH₃) gas may be also used to form a single crystalline silicon layer doped with n-type impurities. Alternatively, the SEG process may be performed by using a carbon source gas, e.g., monomethylsilane (SiH₃CH₃) gas in addition to the silicon source gas, e.g. disilane (Si₂H₆) gas to form a single crystalline silicon carbide layer. In the SEG process, an n-type impurity source gas, e.g., phosphine (PH₃) gas may be also used to form a single crystalline silicon carbide layer doped with n-type impurities.

In other example embodiments, the SEG process may be performed by using a silicon source gas, e.g., dichlorosilane (SiH₂Cl₂) gas, a germanium source gas, e.g., germane (GeH₄) gas to form a single crystalline silicon-germanium layer. In example embodiments, a p-type impurity source gas, e.g., diborane (B₂H₆) gas may be also used to form a single crystalline silicon-germanium layer doped with p-type impurities.

The epitaxial layer 200 including the single crystalline silicon layer doped with n-type impurities or the single crystalline silicon carbide layer doped with n-type impurities, or including the single crystalline silicon-germanium layer doped with p-type impurities may be grown both in horizontal and vertical directions, and thus an upper portion of the epitaxial layer 200 may have a cross-section cut along the second direction of which a shape is pentagon or hexagon.

In example embodiments, the epitaxial layer 200 may fill the recess 180 and cover a lower sidewall of the gate spacer 160.

An ion implantation process may be performed into the active fin 105 to form an impurity region (not shown).

In example embodiments, the impurity region may be formed by implanting n-type impurities, e.g., phosphorous, arsenic, etc. The ion implantation process may be performed by using the dummy gate structures and the gate spacer 160 as an ion implantation mask, and an annealing process may be further performed so that the impurities may be diffused to a portion of the active fin 105.

Accordingly, the impurities may be implanted into both of the epitaxial layer 200 and a portion of the active fin 105 thereunder, and hereinafter, only the portion of the active fin 105 doped with the impurities may be referred to as the impurity region. The epitaxial layer 200 and the impurity region may serve as a source/drain region of a negative-channel metal oxide semiconductor (NMOS) transistor.

In other example embodiments, the impurity region may be formed by implanting p-type impurities, e.g., boron, aluminum, etc., and in this case, the epitaxial layer 200 and the impurity region may serve as a source/drain region of a positive-channel metal oxide semiconductor (PMOS) transistor.

Referring to FIGS. 15 to 17, an etch stop layer 210 may be formed on the dummy gate structures, the gate spacer 160, the epitaxial layer 200 and the isolation layer 120, and a first interlayer insulating layer 220 may be formed on the etch stop layer 210 to have a top surface higher than that of the dummy gate structure.

The etch stop layer 210 may be formed of a nitride, e.g., silicon nitride.

In example embodiments, the first interlayer insulating layer 220 may be formed of a material having a good gap-fill characteristic and a low etch rate with respect to hydrogen fluoride (HF) serving as an etchant in a subsequent process for etching the dummy gate insulation layer pattern 130. For example, the first interlayer insulating layer 220 may be formed of tonen silazene (TOSZ).

The first interlayer insulating layer 220 may be formed of the material having the good gap-fill characteristic, and thus a space between the dummy gate structures may be sufficiently filled with no void therein, even though top surfaces of the dummy gate structures are high.

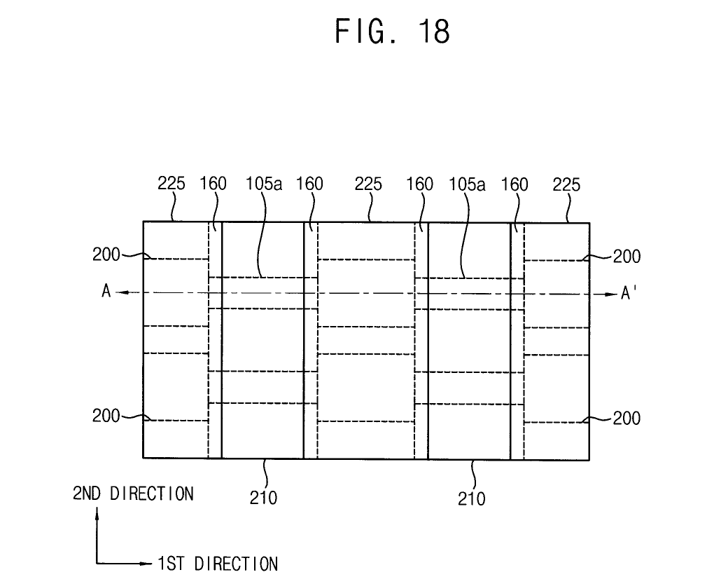

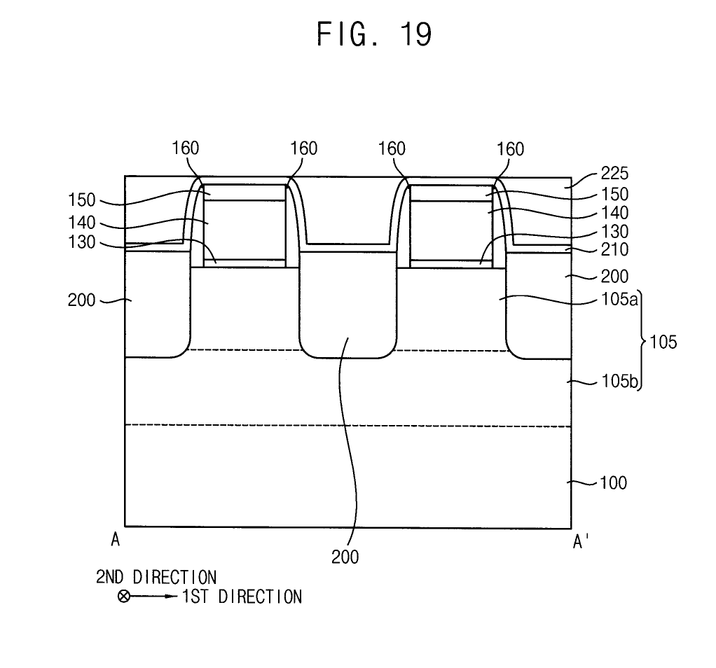

Referring to FIGS. 18 and 19, the first interlayer insulating layer 220 may be planarized until a top surface of the etch stop layer 210 on the gate mask 150 may be exposed to form a first interlayer insulating layer pattern 225.

In example embodiments, the planarization process may be performed by a chemical mechanical polishing (CMP) process and/or an etch back process.

An oxygen plasma treatment process may be performed on the first interlayer insulating layer pattern 225. Thus, the first interlayer insulating layer pattern 225 including, e.g., TOSZ may have a very low etch rate with respect to hydrogen fluoride (HF).

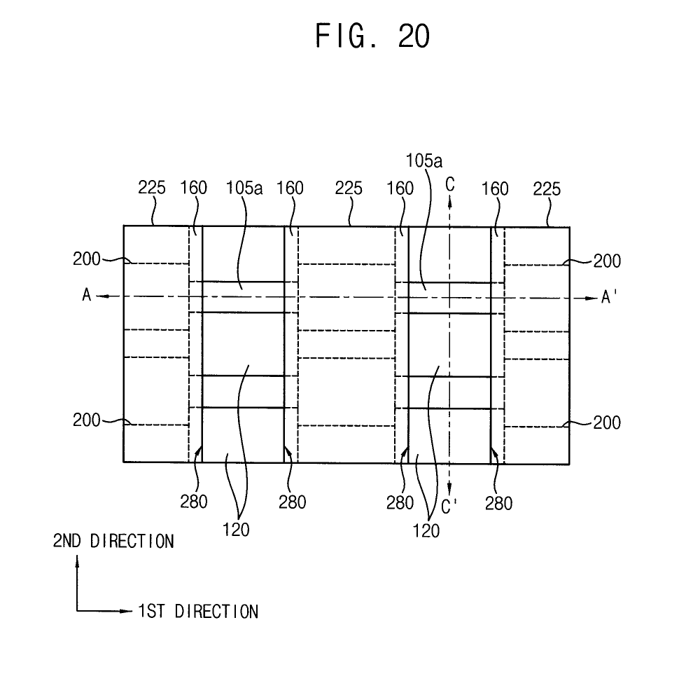

Referring to FIGS. 20 to 22, the exposed portion of the etch stop layer 210 and underlying layers, i.e., the gate mask 150, the dummy gate electrode 140 and the dummy gate insulation layer pattern 130 under the etch stop layer 210 may be removed to form an opening 280 exposing top surfaces of the active fin 105 of the substrate 100 and the isolation layer 120.

In example embodiments, the exposed portion of the etch stop layer 210 and the gate mask 150 may be removed by a dry etch process. Alternatively, the exposed portion of the etch stop layer 210 and the gate mask 150 may be removed by a wet etch process using phosphoric acid (H₃PO₄) as an etchant in addition to the dry etch process. The etch stop layer 210 and the gate mask 150 may include, e.g., silicon nitride, while the gate spacer 160 may include the low-k dielectric material containing oxygen, e.g., silicon oxynitride or silicon oxycarbonitride, and thus the gate spacer 160 may not be removed but remain in the process for etching the etch stop layer 210 and the gate mask 150.

In example embodiments, the dummy gate electrode 140 may be sufficiently removed by performing a dry etch process and then performing a wet etch process.

In example embodiments, the dummy gate insulation layer pattern 130 may be removed by a wet etch process using hydrogen fluoride (HF) as an etchant. The first interlayer insulating layer pattern 225 may include the material having a low etch rate with respect to hydrogen fluoride (HF), e.g., TOSZ, and thus may not be removed or damaged when the process for etching the dummy gate insulation layer pattern 130 is performed. Particularly, the interlayer insulating layer 225 including TOSZ on which the oxygen plasma treatment process has been performed may not be removed or damaged when the process for etching the dummy gate layer pattern 130 is performed.

The etch stop layer 210 may be transformed into an etch stop layer pattern 215 after the exposed portion of the etch stop layer 210 is removed.

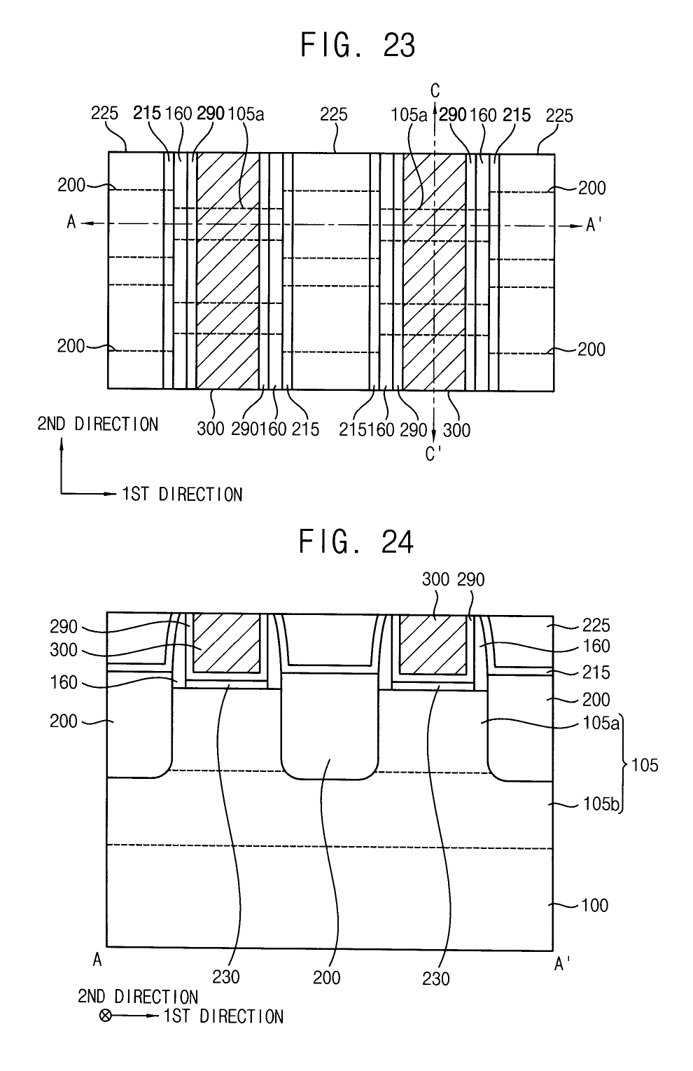

Referring to FIGS. 23 to 25, a gate insulation layer pattern 230, a high-k dielectric layer pattern 290 and a gate electrode 300 may be formed to fill the opening 280.

Particularly, after performing a thermal oxidation process on the top surface of the active fin 105 of the substrate 100 exposed by the opening 280 to form the gate insulation layer pattern 230 including silicon oxide, a high-k dielectric layer may be formed on a top surface of the gate insulation layer pattern 230, a top surface of the isolation layer 120, a sidewall of the opening 280, and a top surface of the first interlayer insulating layer 225, and a gate electrode layer may be formed on the high-k dielectric layer to sufficiently fill a remaining portion of the opening 280.

The high-k dielectric layer may be formed of a metal oxide having a high dielectric constant, e.g., hafnium oxide, tantalum oxide, zirconium oxide, or the like. The gate electrode layer may be formed of a material having a low resistance, e.g., a metal such as aluminum, copper, tantalum, etc., or a metal nitride thereof by an ALD process, a physical vapor deposition (PVD) process, or the like. In an example embodiment, a heat treatment process, e.g., a rapid thermal annealing (RTA) process, a spike rapid thermal annealing (spike RTA) process, a flash rapid thermal annealing (flash RTA) process or a laser annealing process may be further performed. Alternatively, the gate electrode layer may be formed of doped polysilicon.

The gate electrode layer and the high-k dielectric layer may be planarized until the top surface of the first interlayer insulating layer pattern 225 may be exposed to form the high-k dielectric layer pattern 290 on the top surface of the gate insulation layer pattern 230, the top surface of the isolation layer 120, and the sidewall of the opening 280 or the gate spacer 160, and the gate electrode 300 filling the remaining portion of the opening 280 on the high-k dielectric layer pattern 290. Accordingly, a bottom surface and a sidewall of the gate electrode 300 may be surrounded by the high-k dielectric layer pattern 290. In example embodiments, the planarization process may be performed by a CMP process and/or an etch back process.

The gate insulation layer pattern 230, the high-k dielectric layer pattern 290 and the gate electrode 300 sequentially stacked may form a gate structure, and the gate structure and the source/drain region adjacent thereto may form an NMOS transistor or a PMOS transistor.

Referring to FIGS. 26 to 29, a second interlayer insulating layer 320 covering the transistor may be formed on the first interlayer insulating layer pattern 225, and a contact plug 330 may be formed through the second interlayer insulating layer 320, the first interlayer insulating layer pattern 225 and the etch stop layer pattern 215 to contact the epitaxial layer 200.

In example embodiments, the contact plug 330 may be formed as follows. An etching process using the etch stop layer pattern 215 as an etching end point may be performed on the second interlayer insulating layer 320 and the first interlayer insulating layer pattern 225 to form a hole (not shown) therethrough, and a portion of the etch stop layer pattern 215 exposed by the hole may be removed to expose a top surface of the epitaxial layer 200. A conductive layer may be formed on the exposed top surface of the epitaxial layer 200 and the second interlayer insulating layer 320 to sufficiently fill the hole, and the conductive layer may be planarized until a top surface of the second interlayer insulating layer 320 may be exposed to form the contact plug 330.

In example embodiments, the contact plug 330 may be formed to have a linear shape extending in the second direction and contacting the top surfaces of the epitaxial layers 200. Alternatively, a plurality of contact plugs 330 may be formed to have an island-like shape from each other, which may contact the top surfaces of the epitaxial layers 200, respectively.

The semiconductor device may be manufactured by the above processes.

The semiconductor device may include the substrate 100 having the field region in which the isolation layer 120 is formed and the active fin 105 protruding from the isolation layer 120, the gate structure on the active fin 105, the gate spacer 160 including a low-k dielectric material containing oxygen on the sidewall of the gate structure, and the first interlayer insulating layer pattern 225 including, e.g., TOSZ, and surrounding the sidewalls of the gate structure and the gate spacer 160.

The active fin 105 may extend in the first direction, and a plurality of gate structures may be formed in the first direction. The semiconductor device may further include the epitaxial layer 200 between the plurality of gate structures. In example embodiments, the upper portion of the epitaxial layer 200 may have the cross-section cut along the second direction of which a shape is pentagon or hexagon, and a plurality of epitaxial layers 200 may be formed in the second direction.

Additionally, the semiconductor device may further include the etch stop layer pattern 215 formed on the sidewall of the gate spacer 160 and the top surface of the epitaxial layer 200, and the contact plug 330 contacting the epitaxial layer 200 through the first interlayer insulating layer pattern 225 and the etch stop layer pattern 215. The gate structure may include the gate insulation layer pattern 230, the high-k dielectric layer pattern 290 and the gate electrode 300 including a metal sequentially stacked on the active fin 105 of the substrate 100.

FIG. 30 is a cross-sectional view illustrating a semiconductor device in accordance with example embodiments.

The semiconductor device of FIG. 30 may be substantially the same as or similar to the semiconductor device of FIGS. 26 to 29 except for the epitaxial layer. That is, the epitaxial layer 200 of the semiconductor device shown in FIG. 30 may have a shape in which a plurality of epitaxial layers 200 having a pentagonal or hexagonal cross-section cut along the second direction of the semiconductor device shown in FIGS. 26 to 29 is connected to each other. When a plurality of active fins 105 is formed at a relatively small distance from each other, the epitaxial layers 200 growing in the horizontal and vertical directions by a SEG process may be connected to each other so that the epitaxial layer 200 shown in FIG. 30 may be formed

As illustrated above, the first interlayer insulating layer 220 may be formed by using, e.g., TOSZ having a good gap-fill characteristic to fill the space between the dummy gate structures with no void therein. Additionally, TOSZ may have a low etch rate with respect to hydrogen fluoride (HF) serving as an etchant in the process for etching the dummy gate layer pattern 130 of the dummy gate structure, so that the first interlayer insulating layer pattern 225 may not be removed or damaged during the process for etching the dummy gate layer pattern 130. Particularly, the first interlayer insulating layer pattern 225 including TOSZ on which the oxygen plasma treatment process has been performed may have a very low etch rate with respect to hydrogen fluoride (HF). The above semiconductor device and the method of manufacturing the semiconductor device may be applied to various types of memory devices including a transistor having a metal gate electrode that may be formed by a gate-last process. For example, the semiconductor device and the method of manufacturing the same may be applied to logic devices such as central processing units (CPUs), main processing units (MPUs), or application processors (APs), or the like. Additionally, the semiconductor device and the method of manufacturing the same may be applied to volatile memory devices such as DRAM devices or SRAM devices, or non-volatile memory devices such as flash memory devices, PRAM devices, MRAM devices, RRAM devices, or the like.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concepts. Accordingly, all such modifications are intended to be included within the scope of the present inventive concepts as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A method of manufacturing a semiconductor device, the method comprising:
forming a dummy gate structure including a dummy gate insulation layer pattern, a dummy gate electrode and a gate mask on a substrate;
forming an insulating layer including tonen silazane (TOSZ) on the substrate to cover the dummy gate structure;
planarizing the insulating layer until a top surface of the gate mask is exposed to form an insulating layer pattern;
removing the exposed gate mask, the dummy gate electrode and the dummy gate insulation layer pattern to form an opening exposing a surface of the substrate, the dummy gate insulation layer pattern being removed using an etchant including hydrogen fluoride (HF) with the insulating layer pattern substantially remaining; and
forming a gate structure to fill the opening.

2. The method of claim 1, further comprising:
performing an oxygen plasma treatment on the insulating layer pattern.

3. The method of claim 1, prior to forming the insulating interlayer, further comprising:
forming a gate spacer on a sidewall of the dummy gate structure, the gate spacer including a low-k dielectric material containing oxygen, and wherein
the insulating layer is formed on the substrate to cover the dummy gate structure and the gate spacer.

4. The method of claim 3, wherein the gate spacer is formed of silicon oxynitride (SiON) or silicon oxycarbonitride (SiOCN).

5. The method of claim 3, after forming the gate spacer, further comprising:
forming an etch stop layer on the dummy gate structure, the gate spacer and the substrate, and wherein
the insulating layer is formed on the etch stop layer, and the insulating layer pattern is formed by planarizing an upper portion of the insulating layer until a top surface of the etch stop layer is exposed.

6. The method of claim 5, wherein the etch stop layer is formed of silicon nitride.

7. The method of claim 5, prior to forming the etch stop layer, further comprising:
etching an upper portion of the substrate using the dummy gate structure and the gate mask as an etching mask to form a recess; and
forming an epitaxial layer to fill the recess,
and wherein the etch stop layer is formed on the dummy gate structure, the gate spacer and the epitaxial layer.

8. The method of claim 7, further comprising:
forming a contact plug through the insulating layer pattern and the etch stop layer to contact the epitaxial layer.

9. The method of claim 1, wherein the dummy gate electrode is formed of polysilicon, and the gate mask is formed of silicon nitride.

10. The method of claim 9, wherein the removing the exposed gate mask includes performing a dry etch process.

11. The method of claim 10, wherein the removing the exposed gate mask further includes performing a wet etch process using phosphoric acid (H₃PO₄) as an etchant.

12. The method of claim 1, wherein the forming the gate structure includes forming a gate insulation layer pattern, a high-k dielectric layer pattern and a metal gate electrode sequentially stacked on the substrate.

13. The method of claim 12, wherein the gate insulation layer pattern is formed on the exposed surface of the substrate, the high-k dielectric layer pattern is formed on a top surface of the gate insulation layer pattern and a sidewall of the opening, and the metal gate electrode is formed on the high-k dielectric layer pattern so that a bottom surface and a sidewall of the metal gate electrode is covered by the high-k dielectric layer pattern.

14. A method of manufacturing a semiconductor device, the method comprising:
forming an isolation layer on a substrate to define a field region and an active region, the field region being covered by the isolation layer, and the active region not being covered by the isolation layer and protruding from the isolation layer;
forming a dummy gate structure on the active region and the isolation layer, the dummy gate structure including an oxide layer pattern, a dummy gate electrode and a gate mask;
forming an interlayer insulating layer on the active region and the isolation layer to cover the dummy gate structure, the interlayer insulating layer including tonen silazane (TOSZ);
planarizing the interlayer insulating layer until the gate mask is exposed to form an interlayer insulating layer pattern;
removing the exposed gate mask, the dummy gate electrode, and the oxide layer pattern to form an opening exposing surfaces of the active region and the isolation layer, the oxide layer pattern being removed by using an etchant including hydrogen fluoride (HF); and
forming a gate structure to fill at least a portion of the opening, the gate structure including a gate insulation layer pattern, a high-k dielectric layer pattern and a gate electrode.

15. The method of claim 14, further comprising:
performing an oxygen plasma treatment on the interlayer insulating layer pattern.

16. The method of claim 14, prior to forming the insulating interlayer, further comprising:
forming a gate spacer on a sidewall of the dummy gate structure, the gate spacer including a low-k dielectric material containing oxygen, and wherein
the interlayer insulating layer is formed on the active region and the isolation layer to cover the dummy gate structure and the gate spacer.

17. The method of claim 14, wherein
the dummy gate electrode is formed of polysilicon, and the gate mask is formed of silicon nitride, and
the removing the exposed gate mask is performed by a dry etch process and a wet etch process using phosphoric acid (H₃PO₄) as an etchant.

18. A semiconductor device, comprising:
a substrate including a field region and an active region, the field region being covered by an isolation layer thereon, and the active region protruding from the isolation layer;
a gate structure on the active region;
a gate spacer on a sidewall of the gate structure, the gate spacer including a low-k dielectric material containing oxygen; and
an interlayer insulating layer covering sidewalls of the gate structure and the gate spacer and including tonen silazane (TOSZ).

19. The semiconductor device of claim 18, wherein the active region extends in a first direction, and a plurality of gate structures are formed in the first direction,
and further comprising an epitaxial layer on the active region between the plurality of gate structures.

20. The semiconductor device of claim 19, further comprising:
an etch stop layer on a sidewall of the gate spacer and a top surface of the epitaxial layer; and
a contact plug through the interlayer insulating layer and the etch stop layer, the contact plug contacting the epitaxial layer.
